(19) United States
(12) Patent Application Publication
(10) Pub. No.: US 2014/0261657 A1
(43) Pub. Date: Sep. 18, 2014

(54) THIN FILM SOLAR CELL AND METHOD OF FORMING SAME

(71) Applicant: TSMC SOLAR LTD., Taichung City (TW)

(72) Inventors: Tzu-Huan CHENG, Kaohsiung City (TW); Ming-Tien TSAI, Zhubei City (TW)

(73) Assignee: TSMC Solar Ltd., Taichung City (TW)

(21) Appl. No.: 13/856,534

(22) Filed: Apr. 4, 2013

Related U.S. Application Data
(60) Provisional application No. 61/782,057, filed on Mar. 14, 2013.

(51) Int. Cl. H01L 31/0224; H01L 31/18

(52) U.S. Cl. CPC H01L 31/022425; H01L 31/18
USPC 136/256; 438/98

(57) ABSTRACT

A solar cell comprises a back contact layer, an absorber layer on the back contact layer, a buffer layer on the absorber layer, and a front contact layer above the buffer layer. The front contact layer has a first portion and a second portion. The first and second portions of the front contact layer differ from each other in thickness or dopant concentration.

This application claims the benefit of U.S. Provisional Patent Application No. 61/782,057, filed Mar. 14, 2013, which is incorporated by reference herein in its entirety.

### FIELD

This disclosure relates to thin film photovoltaic solar cells and methods of fabricating the same.

### BACKGROUND

Solar cells are photovoltaic components for direct generation of electrical current from sunlight. Due to the growing demand for clean sources of energy, the manufacture of solar cells has expanded dramatically in recent years and continues to expand. Various types of solar cells exist and continue to be developed. Solar cells include absorber layers that absorb the sunlight that is converted into electrical current.

A variety of solar energy collecting modules currently exists. The solar energy collecting modules generally include large, flat substrates and include a back contact layer, an absorber layer, a buffer layer and a front contact layer, which can be a transparent conductive oxide (TCO) material. A plurality of solar cells are formed on one substrate, and are connected in series by respective interconnect structures in each solar cell to form a solar cell module.

Each interconnect structure comprises three scribe lines, referred to as P1, P2 and P3. The P1 scribe line extends through the back contact layer and is filled with the absorber material. The P2 scribe line extends through the buffer layer and the absorber layer and is filled with the (conductive) front contact material. Thus, the P2 scribe line connects the front electrode of a first solar cell to the back electrode of an adjacent solar cell. The P3 scribe line extends through the front contact, buffer and absorber layers.

The portion of the solar cell outside of the interconnect structure is referred to as the active cell, because the interconnect structure does not contribute to the solar energy absorption and generation of electricity. The series resistance of the solar cell module is thus largely dependent on the resistance of the front contact layer and the contact resistance between the front and back contact.

### BRIEF DESCRIPTION OF THE DRAWINGS

FIG. 1 is a cross section of an embodiment of a solar cell described herein, with a low doped front contact layer above a high doped front contact layer.

FIG. 2 is a cross section of a variation of the solar cell of FIG. 1, with a high doped front contact layer above a low doped front contact layer.

FIG. 3 is a plan view of a solar cell module including the solar cell of FIG. 1.

FIG. 4 is a cross section of the solar cell module of FIG. 3, taken across section line 4-4.

FIG. 5 is a plan view of a variation of the solar cell module of FIG. 3.

FIG. 6 is a cross section of the solar cell module of FIG. 5, taken across section line 6-6.

FIG. 7 is a plan view of a variation of the solar cell module of FIG. 3.

FIG. 8 is a cross section of the solar cell module of FIG. 7, taken across section line 8-8.

FIG. 9A is a plan view of a solar cell module including a variation of the solar cell of FIGS. 7 and 8.

FIG. 9B is a cross sectional view of the solar cell module of FIG. 9A, with a low doped front contact layer above a high doped front contact layer.

FIG. 9C is a variation of the solar cell module of FIG. 9B, with a high doped front contact layer above a low doped front contact layer.

FIG. 10A is a plan view of a solar cell module including a variation of the solar cell of FIGS. 7 and 8.

FIG. 10B is a cross sectional view of the solar cell module of FIG. 10A, with a low doped front contact layer above a high doped front contact layer.

FIG. 10C is a variation of the solar cell module of FIG. 10B, with a high doped front contact layer above a low doped front contact layer.

FIG. 11 is a plan view of a variation of the solar cell module of FIG. 3.

FIG. 12 is a cross section of the solar cell module of FIG. 9, taken across section line 12-12.

FIG. 13 is a flow chart of a method of making a solar cell as shown and described herein.

FIG. 14 is a diagram of a photomask suitable for patterning the second front contact layer of FIGS. 3 and 4.

### DETAILED DESCRIPTION

This description of the exemplary embodiments is intended to be read in connection with the accompanying drawings, which are to be considered part of the entire written description. The drawings are not drawn to scale. In the various drawings, like reference numerals indicate like items, unless expressly indicated otherwise in the text.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The front contact (TCO) layer of a solar cell performs a conductive function, while being light transparent. To reduce the series resistance Rs of a solar cell, one can increase the dopant concentration in the TCO layer, or increase the thickness of the TCO layer. Either technique can improve conductivity, but decreases the light transparency of the TCO layer. A reduction in transparency of the TCO layer in turn reduces the amount of energy which reaches the absorber layer and is available for conversion to electricity. Conversely, a thinner TCO layer with a lower dopant concentration provides better light transmission to the absorber layer, but increases the series resistance Rs of the solar cell module.

In some embodiments described herein, the light transmission and electrical resistance of the TCO layer are both improved by selectively controlling TCO layer thickness and/or TCO layer dopant concentration in at least two different regions of the solar cell. For example, by selectively using a higher dopant concentration above the interconnect structure connecting one solar cell to another, the overall TCO resistance is reduced and the optical transmission can be increased at the same time. The higher photo carrier generation due to high TCO transmission and the current flow is mainly collected by the high doped TCO region to reduce the resistance. The improvement of Rs and fill factor (FF) leads to higher efficiency of the solar cell module.

In some embodiments, the selective doping of the TCO layer includes the higher dopant concentration in the interconnect structure, and a lower dopant concentration within the active cell area (outside of the interconnect structure). Because the interconnect structure area does not contribute to photo-current, the high doping in this area can further reduce carrier resistance and interconnect contact resistance, without reducing light collection.

In some embodiments, the selective doping of the TCO layer includes the higher dopant concentration in selected regions outside of the interconnect structure, and a lower dopant concentration in the non-selected areas of the active cell area (outside of the interconnect structure). The higher dopant concentration regions occupy a relatively small portion of the active cell area.

In other embodiments, the selective doping of the TCO layer includes the higher dopant concentration in the interconnect structure, and also distributing the high doping region in a portion of the active area (subcell region), where the portion has a smaller area than the entire area of the active area. The distribution of the higher doped region is dependent on cell width, TCO resistance, absorber quality, and the like.

In various embodiments, the ratio of (the high doped TCO area)/(total cell area) is in a range from 1% to 85% for various device applications.

FIGS. 1 and 2 show two examples of an interconnect structure 170 suitable for use in a solar cell 100 as described herein. Both include a multilayer front electrode 155 having first and second layers 160 and 150 (or 161 and 151). The configurations are the same as each other, except that in FIG. 1, the first front contact layer 160 is over the second front contact layer 150, whereas in FIG. 2, the second front contact layer 151 is over the first front contact layer 161.

Referring first to FIG. 1, the solar cell 100 includes a substrate 110, a back contact layer 120, an absorber layer 130 on the back contact layer 120, a buffer layer 140 on the absorber layer 130, and a front contact layer 150, 160 above the buffer layer.

In some embodiments, the substrate 110 is a glass substrate, such as soda lime glass. In other embodiments, the substrate 110 is a flexible metal foil or polymer (e.g., polyimide). In some embodiments, the substrate 110 has a thickness in a range from 0.1 mm to 5 mm.

In some embodiments, the back contact 120 is formed of molybdenum (Mo) above which a CIGS absorber layer 130 can be formed. In some embodiments, the Mo back contact 120 is formed by sputtering. Other embodiments include other suitable back contact materials. such as Pt, Au, Ag, Ni, or Cu, instead of Mo. For example, in some embodiments, a back contact layer of copper or nickel is provided, above which a cadmium telluride (CdTe) absorber layer can be formed. Following formation of the back contact layer 120, the P1 scribe line is formed in the back contact layer 120. The P1 scribe line is to be filled with the absorber layer material. In some embodiments, the back contact 120 has a thickness from about 10 μm to about 300 μm.

The absorber 130, such as a p-type absorber 130 is formed on the back contact 120. In some embodiments, the absorber layer 130 is a chalcopyrite-based absorber layer comprising Cu(In,Ga)Se₂ (CIGS), having a thickness of about 1 micrometer or more. In some embodiments, the absorber layer 130 is sputtered using a CuGa sputter target (not shown) and an indium-based sputtering target (not shown). In some embodiments, the CuGa material is sputtered first to form one metal precursor layer and the indium-based material is next sputtered to form an indium-containing metal precursor layer on the CuGa metal precursor layer. In other embodiments, the CuGa material and indium-based material are sputtered simultaneously, or on an alternating basis.

In other embodiments, the absorber comprises different materials, such as CuInSe₂ (CIS), CuGaSe₂ (CGS), Cu(In,Ga)Se₂ (CIGS), Cu(In,Ga)(Se,S)₂ (CIGSS), CdTe and amorphous silicon. Other embodiments include still other absorber layer materials.

Other embodiments form the absorber layer by a different technique that provides suitable uniformity of composition. For example the Cu, In, Ga and Seₑ can be coevaporated and simultaneously delivered by chemical vapor deposition (CVD) followed by heating to a temperature in the range of 400° C. to 600° C. In other embodiments, the Cu, In and Ga are delivered first, and then the absorber layer is annealed in an Se atmosphere at a temperature in the range of 400° C. to 600° C.

In some embodiments, the absorber layer 130 has a thickness from about 0.3 μm to about 8 μm.

In some embodiments, the buffer layer can be one of the group consisting of CdS, ZnS, In₂S₃, In₂Se₃, and Zn₁₋ₓMgₓO, (e.g., ZnO). Other suitable buffer layer materials can be used. In some embodiments, the buffer layer 140 has a thickness from about 1 nm to about 500 nm.

The front contact layer comprises a first front contact layer 150 (151) and a second front contact layer 160 (161), both formed above the buffer layer. In various embodiments, the first front contact layer 150 (151) and second front contact layer 160 (161) can be formed of any of the materials listed in Table 1, doped with any one of the dopants corresponding to each material in Table 1.

TABLE 1

| TCO material | Dopant |
|---|---|
| SnO₂ | Sb, F, As, Nb, Ta |
| ZnO | Al, Ga, B, In, Y, Sc, F, V, Si, Ge,Ti, Zr, Hf, Mg, As, H |
| In₂O₃ | Sn, Mo, Ta, W, Zr, F, Ge, Nb, Hf, Mg |
| CdO | In, Sn |
| Ta₂O | |
| GaInO₃ | Sn, Ge |
| CdSb₂O₃ | Y |
| ITO | Sn |

The first and second front contact layers 160, 150 can comprise the same or different TCO material, and can be applied by the same or different methods. For example in some embodiments, a ZnO layer is sputtered over a CVD layer.

The completed solar cell 100 includes an interconnect structure 170 (171). The remainder of the area of the solar cell is the active cell area 180 (181), which effectively absorbs photons. The figures are not to scale, and one of ordinary skill in the art understands that the active area 180 (181) is substantially larger than the interconnect structure 170 (171).

The first front contact layer 160 (161) is provided over the entire solar cell area, (except where it is removed in the P3 scribe line). The second front contact layer 150 (151) can be formed under or over the first front contact layer 160 (161). The second front contact layer 150 (151) is formed over one or more selected portions of the solar cell. The total area covered by the second front contact layer 150 (151) is less than the total area covered by the first front contact layer 160 (161). The second front contact layer 150 (151) can be applied in a manner that reduces series resistance without substantially reducing the light transmitted to the absorber layer 130.

In some embodiments, the first front contact layer 160 (161) has a thickness from about 5 nm to about 3 μm. In some embodiments, the side walls of the first front contact layer 160 within the P2 scribe line are also from about 5 nm to about 3 μm. In some embodiments, the second front contact layer 150 (151) has a thickness from about 5 nm to about 3 μm.

In some embodiments, the first front contact layer has a first dopant concentration, and the second front contact layer has a second dopant concentration that is different from the first dopant concentration.

In some embodiments, the dopant concentration of the first front contact layer 160 (161) is lower than the dopant concentration of the second front contact layer 150 (151). For example in some embodiments, the first front contact layer 150 has a dopant concentration from 1×10¹⁷ cm⁻³ to 8×10²² cm⁻³, and the second front contact layer 160 has a dopant concentration from 1×10¹² cm⁻³ to 5×10²⁰ cm⁻³. In the embodiments shown in FIGS. 1-12, references to the low-doped TCO material can include materials with concentrations in the range from 1×10¹² cm⁻³ to 5×10²⁰ cm³, as used in the first front contact layer 160; and references to the high-doped TCO material can include materials with concentrations in the range from 1×10¹⁷ cm⁻³ to 8×10²² cm⁻³, as used in the second front contact layer 150.

In some embodiments, the first front contact layer 160 (having the lower dopant concentration) is formed on the second front contact layer 150 (having the higher dopant concentration). For example, FIG. 1 shows this configuration.

In other embodiments, the second front contact layer 151 (having the higher dopant concentration) is formed on the first front contact layer 161 (having the lower dopant concentration). For example, FIG. 2 shows a solar cell 101 in which the second front contact layer 151 (having the higher dopant concentration) is formed on the first front contact layer 161 having the lower dopant concentration.

FIGS. 1 and 2 are merely exemplary cross sections, and are not intended to imply that the area of the first front contact layer 150 (151) is the same as the area of the second front contact layer 160 (161) throughout the solar cell. In some embodiments, the second front contact layer covers a smaller area than the first front contact layer. In various embodiments described below, the first front contact layer 150 (151) covers the solar cell, except in the P3 scribe line; and the second front contact layer 160 (161) covers a portion of the solar cell that is smaller in area than the first front contact layer.

By distributing the high doped TCO layer 150 (151) in selective portions of the solar cells 202, the series resistance Rs of the solar cell is improved without impairing the ability of the solar cell to absorb solar radiation. In addition, by including the low doped TCO layer 160 (161) in the remaining area 180 without the high doped TCO layer 150 (151), the transmittance of the solar radiation through the multilayer front contact (comprising first and second front contact layers) is improved.

One of ordinary skill can select the design of FIG. 1 or FIG. 2 that is best suited for a particular design. The configuration of FIG. 1 (low dopant concentration layer on top) has lower series resistance (Rs) than the configuration of FIG. 2. The configuration of FIG. 2 (high dopant concentration layer on top) has higher open circuit voltage Voc and higher shunt resistance (Rsh) than the configuration of FIG. 1.

FIGS. 3-12 show various embodiments in which the high dopant concentration TCO layer is distributed partially in the active cell areas. In some embodiments, the high dopant concentration TCO layer is also located above the interconnect structure (scribe line region).

FIGS. 3 and 4 show an embodiment of a solar cell module 200, which includes selective portions of the second front contact layer 160 either above or below the first front contact layer 150. FIG. 4 is a cross sectional view of a detail of FIG. 3, taken across section line 4-4. The solar cell module 200 has a plurality of solar cells 202. Each solar cell 202 has a respective interconnect structure 170. The interconnect structure 170 comprises a plurality of scribe lines P1, P2, P3 (shown in FIG. 4). The solar cell 202 comprises a plurality of rectangular regions 180, each rectangular region 180 having a plurality of sides with the second front contact layer 150 formed above the buffer layer 140 in an elongated region 201 along at least one of the sides. Each rectangular region 180 has a central region without the second front contact layer 150 therein.

Thus, the horizontal line segments 201 perpendicular to the interconnect regions 170 indicate regions having both high doped and low doped front contact layers 150, 160, and the white regions 180 bounded by the regions 201 (above and below) and the interconnect structures 170 (to the left and right) include the low doped front contact layer 160, but not the high doped front conductive layer 150. Note that in the embodiment of FIGS. 3 and 4, the regions 201 which include both the first and second front contact layers 160, 150 extend across the active cell area, and do not cover the entire interconnect structure 170 throughout the entire length of the interconnect structure 170.

In FIGS. 3 and 4, the second front contact layer 150 (having the higher dopant concentration) is formed in one or more regions 201 extending perpendicular to the plurality of scribe lines P1, P2, P3. In the embodiment of FIGS. 3 and 4, the first front contact layer 160 (with lower dopant concentration) is formed on the first front contact layer 150. The remaining active areas 180 of the solar cells 202 include the first front contact layer 160, without the second front contact area 150. The regions 201 extend perpendicular to the interconnect structures 170 throughout the entire width from one P3 scribe line to the adjacent P3 scribe line. In the embodiment of FIGS. 3 and 4, the regions 201 are staggered, so that the regions 201 in consecutive solar cells are parallel to, but not adjacent to, each other. In other embodiments (not shown), the regions 201 in adjacent solar cells are aligned with each other.

The regions 201 selectively provide higher conductivity conductive paths for transmitting current serially from one solar cell to the next, reducing the overall series resistance Rs of the solar cells 202.

Although the embodiment of FIGS. 3 and 4 has the second front contact layer above the first front contact layer 150, in other embodiments, the first front contact layer 151 is formed on the second front contact layer 161, as shown in FIG. 2.

FIGS. 5 and 6 show an embodiment of a solar cell module 300, which includes selective portions of the second front contact layer 160 either above or below the first front contact layer 150. FIG. 6 is a cross sectional view of a detail of FIG. 5, taken across section line 6-6.

The solar cell module 300 has a plurality of solar cells 302. Each solar cell 302 has a respective interconnect structure 170. The interconnect structure 170 comprises a plurality of scribe lines P1, P2, P3 (shown in FIG. 6). Elongated regions 301 and additional regions 301a are provided at various locations in each solar cell. The lines 301, 301a indicate regions having both high doped and low doped front contact layers 150, 160, and the white regions 180 include the low doped front contact layer 160, but not the high doped front conductive layer 150.

In FIGS. 5 and 6, the second front contact layer 150 (having the higher dopant concentration) is formed in one or more regions 301 extending perpendicular to the plurality of scribe lines P1, P2, P3, and in additional regions 301a connected to the regions 301. In the embodiment of FIGS. 3 and 4, the first front contact layer 160 (with lower dopant concentration) is formed on the first front contact layer 150. The remaining active areas 180 of the solar cells 302 include the first front contact layer 160, without the second front contact area 150. The regions 301 extend perpendicular to the interconnect structures 170 throughout the entire length from one P3 scribe line to the adjacent P3 scribe line. In the embodiment of FIGS. 3 and 4, the regions 301 are staggered, so that the regions 301 in consecutive solar cells are parallel to, but not adjacent to, each other. In other embodiments (not shown), the regions 301 in adjacent solar cells are aligned with each other.

Each region 301 includes a line 301 perpendicular to the scribe lines, and at least one additional region 301a connected to and extending away from the one or more regions 301. In the example shown, each region 301 has two regions 301a connected at an end of the region 301, in an arrow configuration. The configuration of the additional regions 301a is not limited to straight line segments, and curved line segments can be used in other embodiments. The number of additional regions 301a is not limited to two, and any non-negative number of additional regions 301 can be included in other embodiments. In some embodiments, the additional regions 301a extend substantially across the width direction of the solar cells 302. In some embodiments, the additional regions 301a are line segments oriented from about 15 degrees to about 75 degrees away from the scribe lines P1, P2, P3 of the interconnect region 170, for example, about 45 degrees away. In some embodiments, the second front contact layer 150 has two of the additional regions 301a connected on opposite sides of the one or more region 301 and extending a majority of a width of the solar cell 302.

The additional regions 301a occupy a small percentage of the area of the solar cells 302, so as not to substantially reduce the average transmittance of the solar cells 302. The regions 301, 301a selectively provide higher conductivity conductive paths for transmitting current serially from one solar cell to the next, reducing the overall series resistance Rs of the solar cells 302 beyond that achieved in the embodiment of FIGS. 3 and 4.

By distributing the high doped TCO layer 150 in selective portions of the solar cells 302, the series resistance Rs of the solar cell is improved without substantially impairing the ability of the solar cell to absorb solar radiation. In addition, by including a limited area of additional regions 301a with the high doped TCO material, and only including the low doped TCO layer 160 in the remaining area 180, the transmittance of the solar radiation through the front contact 160 is improved.

In some embodiments, the second contact layer 150 extends above at least one of the plurality of scribe lines P1, P2, P3 throughout the length of the scribe lines. In FIGS. 7 and 8, a solar cell 400 comprises: a substrate 110, a back contact layer 120 on the substrate 110, an absorber layer 130 on the back contact layer 120, a buffer layer 140 on the absorber layer 130 and a front contact layer. The front contact layer 155 has a first portion (which can be partially in an interconnect structure area 470 of the solar cell and/or within a portion 401 of the active cell area) and a second portion 180 outside of the interconnect structure area of the solar cell 400, wherein the first and second portions of the front contact layer 155 differ from each other in one of the group consisting of thickness and dopant concentration.

In some embodiments, the first portion 401, 470 of the front contact layer 155 has a first layer 160 with a relatively low dopant concentration and a second layer 150 with a relatively high dopant concentration; and the second portion 180 of the front contact layer 155 includes the first layer 160 with the relatively low dopant concentration (but not the second layer 150).

In some embodiments, the first portion 401, 470 of the front contact layer has a greater thickness than the second portion (due to the presence of both the first and second front contact layers 160, 150).

In some embodiments, the second portion 180 of the front contact layer has a lower dopant concentration than the first portion (due to the absence of the second contact layer 150).

FIGS. 7 and 8 show an embodiment of a solar cell module 400, which includes selective portions of the second front contact layer 160 either above or below the first front contact layer 150. FIG. 8 is a cross sectional view of a detail of FIG. 3, taken across section line 8-8. The solar cell module 400 has a plurality of solar cells 402. Each solar cell has a respective interconnect structure 470. The interconnect structures 470 comprise a plurality of scribe lines P1, P2, P3 (shown in FIG. 4). Interconnect 470 is similar to that described in FIGS. 1-6, except that interconnect structure 470 includes both the high doped TCO layer 150 and the low doped TCO layer 160 along part or all of the entire length, and part or all of the entire width of the interconnect structure 470. Thus, the horizontal lines 201 perpendicular to the interconnect regions 170 indicate regions having both high doped and low doped front contact layers 150, 160, and the white regions 180 bounded by the regions 201 (above and below) and the interconnect structures 170 (to the left and right) include the low doped front contact layer 160, but not the high doped front conductive layer 150. In addition, as best seen in FIG. 8, both the high doped and low doped front contact layers 150, 160 are present above at least a portion of the interconnect structure 470.

FIG. 9A is an enlarged detail of a portion of a solar cell module 400 having two solar cells 402 as shown in FIGS. 7 and 8. In the embodiment of FIG. 9A, the high doped conductive layer 150 is formed over the entire length of the P2 scribe line, and is not included above the remaining area 180 of the solar cell 402. The second front contact layer 150 extends between and not beyond the edges of the P2 scribe line.

In other embodiments (not shown), the high doped conductive layer 150 is formed over only a portion of the entire length of the P2 scribe line, and is not included above the remaining area 180 of the solar cell. In other embodiments (not shown), the additional regions 301a shown in FIG. 5 are included in the remaining area 180 of solar cell 402.

FIG. 9B is a cross sectional view of the solar cell 402 of FIG. 9A, taken across section line 9B-9B. As shown in FIG. 9B, a conformal coating of the high doped TCO material is deposited on the buffer layer 140 to form the second front contact layer 150. A resist (not shown) is applied, and a photomask is used to select which regions of the second front contact layer 150 are to be removed. Using an anisotropic etch (e.g., plasma etch), the second front contact layer 150 is removed from the solar cell 402, except in the selected areas (where the selected areas include the regions 401 and 470. Then the low doped TCO material is deposited as the first front contact layer 160, over the second front contact layer 150. Thus, the relatively thin front contact layer, comprising low-doped first front contact layer 160 is exposed in a substantial portion of the area of the solar cell. The thicker multi-layer TCO layer (comprising the first and second front contact layers 150, 160) having lower transmittance, is selectively formed over a relatively small area.

FIG. 9C is a cross sectional view of a solar cell 404, which is a variation of the solar cell 402 of FIG. 9B. In FIG. 9C the low doped TCO material is deposited on the buffer layer 140 as the first front contact layer 161. Then the high doped TCO material is deposited on the first front contact layer 161 to form the second front contact layer 151. A resist (not shown) is applied, and a photomask is used to select which regions of the second front contact layer 151 are to be removed. After removing the non-selected portions of the second front contact layer, using an anisotropic etch (e.g., plasma etch), the second front contact layer 151 is removed from the solar cell 402, except in the selected areas (where the selected areas include the regions 401 and 470. Thus, the relatively thin, low-doped first front contact layer 161 is exposed in a substantial portion of the area of the solar cell. The thicker, lower transmittance TCO layer comprising the first and second front contact layers 161, 151 is selectively formed over a relatively small area.

Thus, as shown in FIGS. 9B and 9C, respectively, the selected regions of high doped TCO material which constitute the second front contact layer 150 (151) can be formed below or above the regions of low doped TCO material which constitute the first front contact layer 160 (161).

FIG. 10A is an enlarged detail of a portion of a solar cell module 410 having two solar cells 403 similar to that shown in FIGS. 7 and 8. In the embodiment of FIG. 10A, the high doped conductive layer 150 is formed over the elongated regions 401. The layer 150 also extends along the entire length of the P2 scribe line, and extends across the entire width between the P1 scribe line and the P3 scribe line. The high doped conductive layer 150 is not included above the P1 scribe line, the P3 scribe line, or the remaining area 180 of the solar cell 403. In other embodiments (not shown), the high doped conductive layer 150 is formed over only a portion of the entire length of the P2 scribe line, and is not included above the remaining area 180 of the solar cell. In other embodiments (not shown), the additional regions 301a shown in FIG. 5 are included in the remaining area 180 of solar cell 402.

By distributing the high doped TCO layer 150 in selective portions of the solar cells 402 (FIG. 9A) and 403 (FIG. 10), the series resistance Rs of the solar cell is improved without impairing the ability of the solar cell to absorb solar radiation. In addition, but only including the low doped TCO layer 160 in the remaining area 180, the transmittance of the solar radiation through the front contact 160 is improved. Because the interconnect region between the P1 and P3 scribe lines does not absorb solar energy, increasing the width of the second front contact layer 150 (151) in the interconnect region does not substantially affect collection of solar energy.

FIG. 10B is a cross sectional view of the solar cell 403 of FIG. 10A, taken across section line 10B-10B. The solar cell 403 of FIG. 10B is similar to that shown in FIG. 9B, except that the width of the second front contact layer 150 in the interconnect region 470 extends all the way from the edge of the P1 scribe line to the edge of the P3 scribe line. In other respects, the structure and method of FIG. 10B is the same as that described above with respect to FIG. 9B.

FIG. 10C is a cross sectional view of the solar cell 405 of FIG. 10A, taken across section line 10C-10C. The solar cell 403 of FIG. 10C is similar to that shown in FIG. 9C, except that the width of the second front contact layer 150 in the interconnect region 470 extends all the way from the edge of the P1 scribe line to the edge of the P3 scribe line. In other respects, the structure and method of FIG. 10B is the same as that described above with respect to FIG. 9B.

The embodiments of FIGS. 1-10C use an additional mask and photolithography step, but use the same processes that would be used to form a solar cell without the second front contact layer 150 (151). FIGS. 11 and 12 show another solar cell module 500 which improves the series resistance of the solar cell 502 at least in part by replacing the TCO material in the P2 scribe line with a high conductivity material 190 having a higher conductivity than the TCO material. This adds a deposition step for the high conductive material 190.

In some embodiments, the P2 scribe line is filed with a high conductivity material 190 comprising a metal or alloy. In some embodiments, the P2 scribe line is filed with a high conductivity material 190 comprising aluminum, copper, or molybdenum. The higher conductivity material 190 can be included in the P2 scribe line of any of the embodiments described above with reference to FIGS. 1-10C.

The embodiments of FIGS. 7-10C improve the series resistance beyond that achieved in the embodiment of FIGS. 3 and 4.

FIG. 13 is a flow chart of a method of making a solar cell.

At step 1300, a back contact layer is formed on a substrate.

At step 1302, an absorber layer is formed on the back contact layer.

At step 1304, a buffer layer is formed on the absorber layer.

At step 1306, a first front contact layer is formed above the buffer layer; and

At step 1308, a second front contact layer is formed above a portion of the buffer layer. The second front contact layer covers a smaller area than the first front contact layer. The second front contact layer has at least one elongated region extending parallel to or perpendicular to the scribe lines of the solar cell. The second front contact layer has a second dopant concentration different from the first dopant concentration of the first front contact layer. For example, the first dopant concentration can be less than the second dopant concentration. In some embodiments, the scribe lines include a P1 scribe line having a first edge and a P3 scribe line having a second edge distal from the first edge of the P1 scribe line, and the at least one elongated segment is formed between, but not beyond, the first edge and the second edge. In some embodiments, step 1308 is formed after step 1306. In other embodiments, step 1308 is performed before step 1306.

The method of FIG. 13 can be applied with a wide process window. For example the process can tolerate variation in the width of the high dopant concentration TCO regions.

FIG. 14 is a plan view of a photomask 1400 suitable for forming the regions 201 of high dopant concentration layer 150, 151, as shown in FIGS. 3 and 4. The photomask has a plurality of patterns 1402 which extend perpendicular to the direction of the scribe lines P1, P2, P3. One of ordinary skill can readily construct corresponding photomasks corresponding to the configurations of FIGS. 5-12.

As described above, the regions 201, 301, 401, 470 having a higher dopant concentration layer 150 (151) have decreased resistance, improving overall series resistance Rs. The regions 180 having a low dopant concentration layer 160, 161 without the higher dopant concentration layer have increased light transmission, for improved light absorption. The selective doping in the window layer can reduce the overall TCO resistance and increase the optical transmission at the same time. The selective doping in the TCO layer can reduce the overall TCO resistance and increase the optical transmission at the same time. The selective doping in the window layer can reduce the overall TCO resistance and increase the optical transmission at the same time.

The selective doping in the window layer can reduce the overall TCO resistance and increase the optical transmission at the same time.

The doping level and doping area of the high dopant concentration TCO layer can be distributed within the active cell area or over part or all of the module interconnect region. A high dopant concentration region can be embedded over a portion of the active cell region. The distribution can be varied, dependent on cell width, TCO resistance, absorber quality, and the like. The interconnect region does not contribute to photocurrent, so placement of a high dopant concentration region above the interconnect can further reduce carrier resistance and interconnect contact resistance.

Although particular examples are described above, the structures and methods described herein can be applied to a broad variety of thin film solar cells, such as a-Si thin film, CIGS, and CdTe with pn junction, p-i-n structure, MIS structure, multi-junction, and the like.

In some embodiments, a solar cell includes at least two TCO (front contact) layers to form the special doping distribution.

In some embodiments, a solar cell includes at least one TCO layer and a conductive film (having higher conductivity than the TCO material) filling the P2 scribe line, to form the special resistivity distribution. The material can be aluminum, copper, or molybdenum, for example.

The solar described herein has a solar cell efficiency that is improved by 3% to 5%.

In some embodiments, a solar cell, comprises a back contact layer, an absorber layer on the back contact layer, a buffer layer on the absorber layer, and a front contact layer above the buffer layer. The front contact layer has a first portion and a second portion, wherein the first and second portions of the front contact layer differ from each other in one of the group consisting of thickness and dopant concentration.

In some embodiments, the first portion of the front contact layer has a greater thickness than the second portion.

In some embodiments, the first portion is in an interconnect structure area of the solar cell and the second portion is outside of the interconnect structure area of the solar cell, and wherein the second portion of the front contact layer has a lower dopant concentration than the first portion.

In some embodiments, a solar cell comprises: a back contact layer, an absorber layer on the back contact layer, a buffer layer on the absorber layer, a first front contact layer above the buffer layer, the first front contact layer having a first dopant concentration, and a second front contact layer above a portion of the buffer layer. The second front contact layer covers a smaller area than the first front contact layer. The second front contact layer has a second dopant concentration that is different from the first dopant concentration.

In some embodiments, the dopant concentration of the first front contact layer is lower than the dopant concentration of the second front contact layer, and the first front contact layer is formed on the second front contact layer.

In some embodiments, the dopant concentration of the first front contact layer is lower than the dopant concentration of the second front contact layer, and the second front contact layer is formed on the first front contact layer.

In some embodiments, the first front contact layer has a dopant concentration from 1×10¹² cm-3 to 5×10²⁰ cm-3, and the second front contact layer has a dopant concentration from 1×10¹⁷ cm-3 to 8×10²² cm-3.

In some embodiments, the solar cell has an interconnect structure comprising a plurality of scribe lines, and the second front contact layer is formed in one or more regions extending perpendicular to the plurality of scribe lines.

In some embodiments, the second front contact layer has at least one additional region connected to and extending away from the one or more regions.

In some embodiments, the second front contact layer has two of the additional regions connected on opposite sides of the one or more region and extending a majority of a width of the solar cell.

In some embodiments, the interconnect structure of the solar cell has a plurality of scribe lines, and the second contact layer extends above at least one of the plurality of scribe lines throughout a length thereof.

In some embodiments, the interconnect structure has a first scribe line in the back contact layer and a second scribe line extending through the absorber layer, buffer layer and the first front contact layer, wherein the second front contact layer extends between but not beyond the first scribe line and the second scribe line.

In some embodiments, the interconnect structure has a scribe line extending through the absorber layer and the buffer layer, the scribe line having edges, and the second front contact layer extends between and not beyond the edges of the scribe line.

In some embodiments, the interconnect structure has a scribe line extending through the absorber layer and the buffer layer, the scribe line filled with a material having a higher conductivity than the first front contact layer and the second front contact layer.

In some embodiments, the solar cell comprises a plurality of rectangular regions, each rectangular region having a plurality of sides with the second front contact layer formed above the buffer layer along the sides, each rectangular region having a central region without the second front contact layer therein.

In some embodiments, a method of making a solar cell comprises: forming a back contact layer on a substrate, forming an absorber layer on the back contact layer, forming a buffer layer on the absorber layer, forming a first front contact layer above the buffer layer, and forming a second front contact layer above a portion of the buffer layer, the second front contact layer covering a smaller area than the first front contact layer.

In some embodiments, the first front contact layer has a first dopant concentration, and the second front contact layer has a second dopant concentration, the first dopant concentration being less than the second dopant concentration.

In some embodiments, the solar cell has an interconnect structure comprising a plurality of scribe lines, and the step of forming the second front contact layer includes forming the second contact layer in at least one elongated segment extending perpendicular to the scribe lines.

In some embodiments, the step of forming the second front contact layer further includes forming the second contact layer in at least one elongated segment extending parallel to the scribe lines.

In some embodiments, the scribe lines include a first scribe line having a first edge and a second scribe line having a second edge distal from the first edge of the first scribe line, and the at least one elongated segment is formed between but not beyond the first edge and the second edge.

Although the subject matter has been described in terms of exemplary embodiments, it is not limited thereto. Rather, the appended claims should be construed broadly, to include other variants and embodiments, which may be made by those skilled in the art.

What is claimed is:

1. A solar cell, comprising:
a back contact layer;
an absorber layer on the back contact layer;
a buffer layer on the absorber layer; and
a front contact layer above the buffer layer, the front contact layer having a first portion and a second portion, wherein the first and second portions of the front contact layer differ from each other in one of the group consisting of thickness and dopant concentration.

2. The solar cell of claim 1, wherein the second portion of the front contact layer has a greater area than the first portion.

3. The solar cell of claim 1, wherein the first portion is in an interconnect structure area of the solar cell and the second portion has larger than 50% of its area outside of the interconnect structure area of the solar cell, and wherein the second portion of the front contact layer has a lower dopant concentration than the first portion.

4. A solar cell comprising:
a back contact layer;
an absorber layer on the back contact layer;
a buffer layer on the absorber layer; and
a first front contact layer above the buffer layer, the first front contact layer having a first dopant concentration; and
a second front contact layer above a portion of the buffer layer, the second front contact layer covering a smaller area than the first front contact layer, the second front contact layer having a second dopant concentration that is different from the first dopant concentration.

5. The solar cell of claim 4, wherein the dopant concentration of the first front contact layer is lower than the dopant concentration of the second front contact layer, and the first front contact layer is formed on the second front contact layer.

6. The solar cell of claim 4, wherein the dopant concentration of the first front contact layer is lower than the dopant concentration of the second front contact layer, and the second front contact layer is formed on the first front contact layer.

7. The solar cell of claim 4, wherein the first front contact layer has a dopant concentration from 1×10¹² cm⁻³ to 5×10²⁰ cm⁻³, and the second front contact layer has a dopant concentration from 1×10¹⁷ cm⁻³ to 8×10²² cm⁻³.

8. The solar cell of claim 4, wherein:
the solar cell has an interconnect structure comprising a plurality of scribe lines; and
the second front contact layer is formed in one or more regions extending perpendicular to the plurality of scribe lines.

9. The solar cell of claim 8, wherein the second front contact layer has at least one additional region connected to and extending away from the one or more regions.

10. The solar cell of claim 9, wherein the second front contact layer has two of the additional regions connected on opposite sides of the one or more region and extending a majority of a width of the solar cell.

11. The solar cell of claim 4, wherein:
the interconnect structure of the solar cell has a plurality of scribe lines; and
the second contact layer extends above at least one of the plurality of scribe lines throughout a length thereof.

12. The solar cell of claim 4, wherein:
the interconnect structure has a first scribe line in the back contact layer and a second scribe line extending through the absorber layer, buffer layer and the first front contact layer;
wherein the second front contact layer extends between but not beyond the first scribe line and the second scribe line.

13. The solar cell of claim 4, wherein:
the interconnect structure has a scribe line extending through the absorber layer and the buffer layer, the scribe line having edges;
wherein the second front contact layer extends between and not beyond the edges of the scribe line.

14. The solar cell of claim 4, wherein:
the interconnect structure has a scribe line extending through the absorber layer and the buffer layer, the scribe line filled with a material having a higher conductivity than the first front contact layer.

15. The solar cell of claim 4, wherein the solar cell comprises a plurality of rectangular regions, each rectangular region having a plurality of sides with the second front contact layer formed above the buffer layer along the sides, each rectangular region having a central region without the second front contact layer therein.

16. A method of making a solar cell, comprising:
forming a back contact layer on a substrate;
forming an absorber layer on the back contact layer;
forming a buffer layer on the absorber layer; and
forming a first front contact layer above the buffer layer; and
forming a second front contact layer above a portion of the buffer layer, the second front contact layer covering a smaller area than the first front contact layer.

17. The method of claim 16, wherein the first front contact layer has a first dopant concentration, and the second front contact layer has a second dopant concentration, the first dopant concentration being less than the second dopant concentration.

18. The method of claim 16, wherein the solar cell has an interconnect structure comprising a plurality of scribe lines, and the step of forming the second front contact layer includes forming the second contact layer in at least one elongated segment extending perpendicular to the scribe lines.

19. The method of claim 18, wherein the step of forming the second front contact layer further includes forming the second contact layer in at least one elongated segment extending parallel to the scribe lines.

20. The method of claim 19, wherein
the scribe lines include a first scribe line having a first edge and a second scribe line having a second edge distal from the first edge of the first scribe line, and
the at least one elongated segment is formed between but not beyond the first edge and the second edge.
